(19) United States
(12) Patent Application Publication
(10) Pub. No.: US 2009/0068833 A1
(43) Pub. Date: Mar. 12, 2009

(54) METHOD OF FORMING CONTACT HOLE OF SEMICONDUCTOR DEVICE

(75) Inventor: Yun Je Choi, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,851

(22) Filed: Jun. 27, 2008

(30) Foreign Application Priority Data
Sep. 7, 2007 (KR) 10-2007-0090893

(51) Int. Cl. H01L 21/768

(52) U.S. Cl. 438/637; 257/E21.577

(57) ABSTRACT

The present invention relates to a method of forming a contact hole of a semiconductor device. According to the method of forming a contact hole of a semiconductor device, a semiconductor substrate in which gates and junctions are formed is provided. A self-aligned contact (SAC) nitride layer is formed on a surface of the gates. A pre-metal dielectric layer is formed on the SAC nitride layer. A contact hole is formed to thereby expose the junction between the gates. A passivation layer is formed on sidewalls of the contact hole. A contact plug is formed, thus gap-filling the contact hole.

### CROSS-REFERENCES TO RELATED APPLICATIONS

The present application claims priority to Korean patent application number 10-2007-0090893, filed on Sep. 7, 2007, which is incorporated by reference in its entirety.

### BACKGROUND OF THE INVENTION

The present invention relates to a semiconductor device and, more particularly, to a method of forming a contact hole of a semiconductor device, which can prevent self-aligned contact (SAC) fail when forming the contact hole using a SAC process.

In general, a semiconductor device includes a number of unit elements therein. With higher semiconductor device integration, the design rule decreases and the size of a semiconductor element formed within a cell becomes smaller. Therefore, difficulties can occur in the manufacturing process of the semiconductor elements constituting the cell.

Meanwhile, in the integration process several elements constituting the semiconductor device have a stacked structure. Accordingly, a contact plug (or a pad concept) has been used to connect different layers. In order to form this contact, structures having a high aspect ratio must be etched. To solve this problem, a SAC process for obtaining an etch profile employing the etch selectivity between two materials (for example, an oxide layer and a nitride layer) has been introduced. For this SAC process, a SAC nitride layer, a spacer, etc., which employ a nitride layer, etc. are necessary so as to prevent attack (i.e., damage) to the underlying gate.

A process of forming a contact plug for a semiconductor device using a general SAC process is described below in short. First, an insulating layer is deposited on a semiconductor substrate in which a gate and junctions are formed. A spacer etch process is then performed to form spacers on both sidewalls of the gate. A SAC nitride layer and a pre-metal dielectric layer are sequentially formed over the semiconductor substrate including the spacers. Next, the pre-metal dielectric layer and the SAC nitride layer over the junctions formed in the semiconductor substrate are etched, forming contact holes through which the junctions are exposed. A polysilicon layer is deposited on the pre-metal dielectric layer, including the contact holes, and then polished to thereby form a contact plug that gap-fills the contact hole.

If the contact holes are formed using the above method, a problem arises because the SAC nitride layer on the upper sidewalls of the gate can be attacked (i.e., etched away) because the distance between gates has become narrow. However, if a contact hole opening is reduced, a source resistance value of a NAND flash device using a common source is increased, causing under program error during device operation. Thus, there are limits to a reduction in the size of the contact hole opening. If misalignment occurs, although an etch recipe having a high etch selectivity with respect to the SAC nitride layer is used, a process for etching the SAC nitride layer formed on the semiconductor substrate is required. Accordingly, there is a problem where the SAC nitride layer is attacked.

If the SAC nitride layer is attacked as described above, SAC failure occurs or the spacers are lost in a pre-cleaning process before a conductive layer for forming the contact plug is deposited. Consequently, a bridge between the gate and the contact plug is generated, thus degrading reliability of the devices.

### BRIEF SUMMARY OF THE INVENTION

The present invention relates to a method of forming a contact hole of a semiconductor device, in which a passivation layer is formed on the sidewalls of the contact hole, thus preventing SAC failure and a bridge between a gate and a contact plug.

A method of forming a contact hole of a semiconductor device in accordance with an aspect of the present invention includes providing a semiconductor substrate in which gates and junctions are formed, forming a self-aligned contact (SAC) nitride layer on a surface of the gates, forming a pre-metal dielectric layer on the SAC nitride layer, forming a contact hole to expose the junction between the gates, forming a passivation layer on sidewalls of the contact hole, and forming a contact plug to gap-fill the contact hole.

A cleaning process can be performed between the formation of the passivation layer and the formation of the contact plug.

The passivation layer can be formed from material having an etch selectivity different from that of the pre-metal dielectric layer. The passivation layer can be formed to a thickness of 50 to 300 angstroms using a silicon nitride (Si₃N₄) layer or a silicon oxynitride (SiON) layer. The passivation layer can be formed by a low-pressure chemical vapor deposition (LPCVD) method or a plasma-enhanced CVD (PECVD) method.

The formation of the passivation layer can include depositing the passivation layer on the pre-metal dielectric layer including the contact hole, and etching the passivation layer so that the passivation layer remains only on the sidewalls of the contact hole.

The passivation layer can be etched by an etchback process. The etchback process can be carried out using a high-density plasma (HDP) etch apparatus at a pressure of 0 to 50 mT. The HDP etch apparatus can use an inductively coupled plasma (ICP) type or a radio frequency (RF) power as a plasma source. A spacer can be further formed on both sidewalls of the gate.

### BRIEF DESCRIPTION OF THE DRAWINGS

FIGS. 1A to 1D are sectional views illustrating a method of forming a contact hole of a semiconductor device in accordance with an embodiment of the present invention.

### DESCRIPTION OF SPECIFIC EMBODIMENTS

A specific embodiment according to the present invention will be described with reference to the accompanying drawings. However, the present invention is not limited to the disclosed embodiment, but may be implemented in various manners. The embodiment is provided to complete the disclosure of the present invention and to allow those having ordinary skill in the art to understand the scope of the present invention. The present invention is defined by the category of the claims.

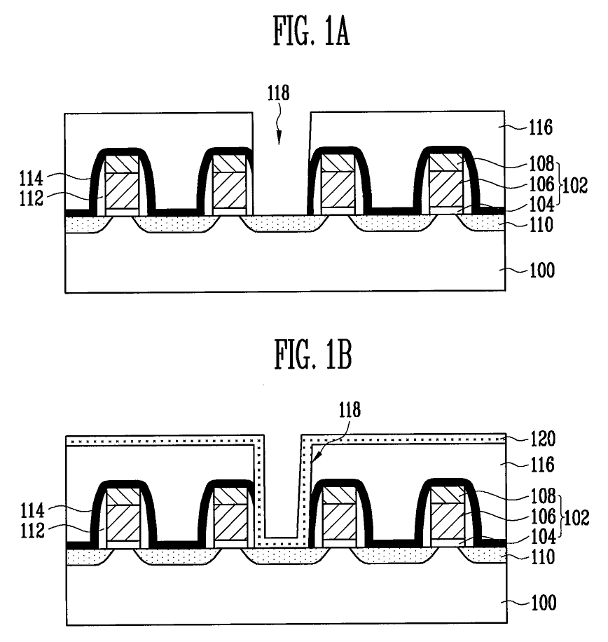

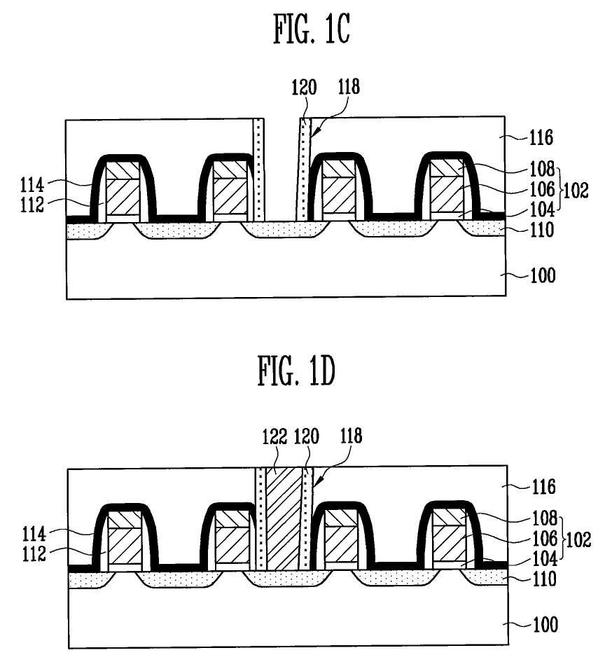

FIGS. 1A to 1D are sectional views illustrating a method of forming a contact hole of a semiconductor device in accordance with an embodiment of the present invention.

Referring to FIG. 1A, specific structures, such as gates 102 (with spacers 112 formed on both sides) and junctions 110, are formed in a semiconductor substrate 100. A SAC nitride layer 114 and a pre-metal dielectric layer 116 are formed over the semiconductor substrate 100 including the specific structures. The gates 102, the junctions 110 and the spacer 112 can be formed by a typical semiconductor manufacturing process.

In the case of a semiconductor device, the gate 102 can have a structure in which a gate dielectric layer 104, a conductive layer pattern 106 and a hard mask pattern 108 are stacked. The gates 102 are also spaced apart from each other at specific intervals. In order to lower the resistance of the gate 102, the conductive layer pattern 106 can include a metal silicide layer. The gate dielectric layer 104 can be formed from a silicon oxide (SiO₂) layer. In this case, the gate dielectric layer 104 can be formed using an oxidization process. The conductive layer patterns 106 can be constructed to have a stacked structure with a polysilicon layer, a metal layer, a polysilicon layer and a metal silicide layer or a stacked structure with a metal layer and a metal suicide layer. The metal silicide layer can be formed using tungsten silicide (WSix).

In the case of a flash memory device, the gate 102 can be formed as the gate of a select transistor. The select transistor can be a source select transistor or a drain select transistor.

The junction 110 can be formed in the semiconductor substrate 100 between the gates 102. The junction 110 can be formed by a typical ion implantation process for injecting an impurity. The spacer 112 formed from an insulating layer can be formed on both sidewalls of the gate 102. The spacer 112 can be formed from an oxide layer.

Meanwhile, in the case of a flash memory device, the spacer 112 can also be formed on both sidewalls of the gate of the select transistor. Although not shown in the drawing, a gap between the gate of the select transistor and the gate of a neighboring memory cell and a gap between the gates of memory cells is narrower than a gap between the gates of the select transistors and, therefore, gap-filled with an insulating layer.

Next, the SAC nitride layer 114 is formed on the entire surface, including the gate 102 and the semiconductor substrate 100. The pre-metal dielectric layer 116 is formed on the SAC nitride layer 114. The SAC nitride layer 114 functions as an etch-stop layer in a subsequent process and can be formed from a silicon nitride (Si₃N₄) layer. The pre-metal dielectric layer 116 can be formed from other types of oxide-based material. For example, the pre-metal dielectric layer 116 can be formed from one selected from a group, including spin on glass (SOG), boron-phosphorus silicate glass (BPSG), plasma-enhanced tetra ethyl ortho silicate (PETEOS), undoped silicate glass (USG), phosphorus silicate glass (PSG) and high-density plasma (HDP) oxide. The pre-metal dielectric layer 116 can be formed through deposition and polishing processes. The polishing process can be performed using a chemical mechanical polishing (CMP) process.

Thereafter, the pre-metal dielectric layer 116 and the SAC nitride layer 114, which correspond to the junctions 110, are etched by an etch process employing a mask (not shown). In the etch process of the SAC nitride layer 114, an etch recipe having a high etch selectivity with respect to the SAC nitride layer 114 rather than the pre-metal dielectric layer 116, or an etch recipe not having an etch selectivity with respect to the SAC nitride layer 114 rather than the pre-metal dielectric layer 116 can be used.

In the latter case, since the bottom area of the contact can be secured, it is advantageous in terms of an improved contact resistance Rc and source line resistance Rs. Accordingly, a contact hole 118 which exposes the junction 110 is formed. When the contact hole 118 is formed, the SAC nitride layer 114 on the sidewalls of the gate 102 can be attacked due to misalignment, etc., so that the SAC nitride layer 114 can be lost partially.

Referring to FIG. 1B, a passivation layer 120 is formed on the pre-metal dielectric layer 116 including the contact hole 118. The passivation layer 120 functions to prevent the spacer 110 from being damaged due to the loss of the SAC nitride layer 114 in a pre-cleaning process which is performed before a conductive layer for forming a contact plug is deposited. Here, the SAC nitride layer 114 functions to protects the gate dielectric layer 104 from hydrogen (H₂), fluorine (F), electric charges, etc., which affect the film quality of the gate dielectric layer 104, and remains until a subsequent contact plug formation process is completed. The passivation layer 120 can be formed from material having an etch selectivity different from that of the pre-metal dielectric layer 116, for example, silicon nitride (Si₃N₄) or silicon oxynitride (SiON).

The passivation layer 120 can be formed to a thickness of 50 to 300 angstroms by a chemical vapor deposition (CVD) method, for example, a low-pressure CVD (LPCVD) method or a plasma-enhanced CVD (PECVD) method.

Referring to FIG. 1C, an etch process is performed on the passivation layer 120 such that the passivation layer 120 remains only the sidewalls of the contact hole 118. The etch process can be performed using an etchback process, for example, a dry etch process.

If the etchback process is performed on the passivation layer 120 under a low density or high-pressure condition, the sidewalls of the passivation layer 120 are attacked, eliminating the effect of the passivation layer. Thus, the etchback process is carried out using a HDP etch apparatus at a low pressure, for example, 0 to 50 mT. The HDP etch apparatus can use an inductively coupled plasma (ICP) type or a radio frequency (RF) power as a plasma source.

Thus, a horizontal portion of the passivation layer 120 is removed through the etchback process, so the passivation layer 120 remains only on the sidewalls of the contact hole 118. As the passivation layer 120 is formed on the sidewalls of the contact hole 118 as described above, SAC fail can be prevented and reliability of the device can be secured although the SAC nitride layer 114 is attacked.

After the passivation layer 120 is formed on the sidewalls of the contact hole 118, a pre-cleaning process is carried out before a conductive layer (for forming a subsequent contact plug) is deposited. The pre-cleaning process can be performed using a diluted HF (DHF) solution or buffered oxide etchant (BOE).

Referring to FIG. 1D, conductive material is deposited on the pre-metal dielectric layer 116, including the passivation layer 120, so that the contact hole 118 is gap-filled. The conductive material is polished to thereby form a contact plug 122.

As described above, a bridge between the gate 102 and the contact plug 122 after the contact plug 122 is formed can be prevented by the passivation layer 120, so reliability of the device can be secured. Further, the SAC nitride layer 114 remains until the contact plug 122 is completely formed. Thus, the gate dielectric layer 104 can be protected from hydrogen (H₂), fluorine (F), electric charges, etc., so the film characteristics of the gate dielectric layer 104 can be secured.

As described above, the present invention has the following advantages.

First, when the contact hole is formed by the SAC process, the passivation layer is formed on the sidewalls of the contact hole. Therefore, although the SAC nitride layer is attacked, SAC fail can be prevented and a bridge between the gate and the contact plug can be prevented.

Second, the SAC nitride layer remains until the contact plug is formed. Accordingly, the gate dielectric layer can be protected from hydrogen (H₂), fluorine (F), electric charge, etc., so that the film characteristics of the gate dielectric layer can be secured.

Third, since SAC fail and a bridge between the gate and the contact plug can be prevented and the film characteristics of the gate dielectric layer can be secured, reliability of devices can be secured.

The embodiment disclosed herein has been proposed to allow a person skilled in the art to easily implement the present invention, and the person skilled in the part may implement the present invention in various manners. Therefore, the scope of the present invention is not limited by or to the embodiment as described above, and should be construed to be defined only by the appended claims and their equivalents.

What is claimed is:

1. A method for forming a contact hole of a semiconductor device, the method comprising:
providing a semiconductor substrate in which gates and junctions are formed;
forming a self-aligned contact (SAC) nitride layer on a surface of the gates;
forming a pre-metal dielectric layer on the SAC nitride layer;
forming a contact hole to expose a junction between the gates;
forming a passivation layer on sidewalls of the contact hole; and
forming a contact plug to gap-fill the contact hole, the contact plug contacting the junction.

2. The method of claim 1, further comprising performing a cleaning process between the formation of the passivation layer and the formation of the contact plug.

3. The method of claim 1, wherein the passivation layer is formed from material having an etch selectivity different from that of the pre-metal dielectric layer.

4. The method of claim 3, wherein the passivation layer is formed of a silicon nitride (Si₃N₄) layer or a silicon oxynitride (SiON) layer.

5. The method of claim 1, wherein the passivation layer is formed to a thickness of 50 to 300 angstroms.

6. The method of claim 1, wherein the passivation layer is formed using a low-pressure chemical vapor deposition (LPCVD) method or a plasma-enhanced CVD (PECVD) method.

7. The method of claim 1, wherein the formation of the passivation layer comprises:
depositing the passivation layer on the pre-metal dielectric layer and within the contact hole, the passivation layer being conformal to the contact hole; and
etching the passivation layer so that the passivation layer remains only on the sidewalls of the contact hole.

8. The method of claim 7, wherein the passivation layer is etched by an etchback process.

9. The method of claim 8, wherein the etchback process is carried out using a high-density plasma (HDP) etch apparatus at a pressure of no more than 50 mT.

10. The method of claim 9, wherein the HDP etch apparatus uses an inductively coupled plasma (ICP) type or a radio frequency (RF) power as a plasma source.

11. The method of claim 1, wherein a spacer is further formed on both sidewalls of the gate.
